(19) United States
(12) Patent Application Publication
(10) Pub. No.: US 2007/0000873 A1
(43) Pub. Date: Jan. 4, 2007

(54) Substrate processing method and semiconductor device manufacturing method

(76) Inventors: Takeo Kubota, Yokohama-shi (JP); Atsushi Shigeta, Fujisawa-shi (JP); Gen Toyota, Oita-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/449,686

(22) Filed: Jun. 9, 2006

(30) Foreign Application Priority Data
Jun. 30, 2005 (JP) 2005-193136

(51) Int. Cl. B44C 1/22; C03C 15/00; C23F 1/00; H01L 21/302

(52) U.S. Cl. 216/88; 438/745; 216/83; 216/91

(57) ABSTRACT

There is disclosed a substrate processing method of polishing a peripheral portion of a substrate to-be-processed by sliding a polishing member and the peripheral portion of the substrate to each other to remove a SiN film deposited on the peripheral portion of the substrate. The method includes supplying a solution containing at least one of polyethyleneimine and tetramethylammonium hydroxide to a slide portion between the peripheral portion of the substrate and the polishing member.

### CROSS-REFERENCE TO RELATED APPLICATIONS

This application is based upon and claims the benefit of priority from prior Japanese Patent Application No. 2005-193136, filed Jun. 30, 2005, the entire contents of which are incorporated herein by reference.

### BACKGROUND OF THE INVENTION

1. Field of the Invention

The present invention relates to a substrate processing method of polishing a peripheral portion of a substrate to-be-processed (referred to as “substrate”, hereinafter), such as a semiconductor wafer. More specifically, the present invention relates to a substrate processing method of removing a SiN (silicon nitride) film deposited on a peripheral portion and to a semiconductor device manufacturing method.

2. Description of the Related Art

In a semiconductor device manufacturing process, material films deposited on a peripheral portion (an edge portion, bevel portion, and notch portion) become sources of contamination in subsequent processing steps. Thus, such material films have to be removed, however it is difficult to remove those material films by etching such as CDE (Chemical Dry Etching).

To overcome the problem, a method of polishing a wafer peripheral portion is recently employed to remove such a material film deposited on the peripheral portion of a wafer to become a source of contamination (Japanese Patent Application KOKAI Publication No. 2003-234314, for example). According to this method, a wafer is rotated, and concurrently, a polishing tape is applied on the peripheral portion of the wafer, thereby polishing the peripheral portion of the wafer. In this manner, the material film deposited on the peripheral portion of the wafer to become a source of contamination can be removed.

However, a problem exists in the above-described method. That is, in the case that the material film deposited on the peripheral portion of the semiconductor wafer is SiN, the SiN film is generally firmly adhered on the peripheral portion, and thus it takes a long polishing time to remove the SiN film from the peripheral portion. Especially, when polishing is carried out by using an expensive polishing tape coated with diamond abrasive, it is preferable that the polishing is completed as short a time as possible in order to reduce the amount of use of the tape. However, when the mechanical polishing force onto the wafer peripheral portion are increased to reduce the polishing time, there are included defects resulting from, for example, wafer slippage, thereby leading to a problem of causing cracking of the wafer in subsequent heat treatment.

### BRIEF SUMMARY OF THE INVENTION

According to an aspect of the present invention, there is provided a substrate processing method of polishing a peripheral portion of a substrate to-be-processed by sliding a polishing member and the peripheral portion of the substrate to each other to remove a SiN film deposited on the peripheral portion of the substrate, the method comprising:

supplying a solution containing at least one of polyethyleneimine and tetramethylammonium hydroxide to a slide portion between the peripheral portion of the substrate and the polishing member.

According to another aspect of the present invention, there is provided a semiconductor device manufacturing method comprising:

forming an insulation film containing SiN above a semiconductor wafer;

forming a resist pattern on the insulation film;

forming a trench passing through the insulation film and extending in a surface region of the semiconductor wafer by etching the insulation film and the semiconductor wafer, using the resist pattern as a mask;

removing the resist pattern; and

removing an undesired portion of the insulation film deposited on a peripheral portion of the semiconductor wafer by sliding the peripheral portion of the semiconductor wafer and a polishing member to each other while supplying a solution containing at least one selected from polyethyleneimine and tetramethylammonium hydroxide to a slide portion between the peripheral portion of the semiconductor wafer and the polishing member.

### BRIEF DESCRIPTION OF THE SEVERAL VIEWS OF THE DRAWING

FIG. 1 is a plan view showing a schematic configuration of a substrate processing apparatus according to a first embodiment of the present invention;

FIG. 2 is a cross-sectional view taken along the line II-II of FIG. 1;

FIG. 3 is a plan view showing a schematic configuration of a substrate processing apparatus according to a second embodiment of the present invention;

FIG. 4 is a view showing a contact state between a notch portion of a wafer and a polishing tape according to the second embodiment of the present invention;

FIG. 5 is a perspective view showing a schematic configuration of the substrate processing apparatus using a polishing head;

FIG. 6 is a cross-sectional view of a device structure in a manufacturing step of a semiconductor device manufacturing method according to a third embodiment of the present invention;

FIG. 7 is a cross-sectional view of the device structure in a manufacturing step subsequent to the manufacturing step of FIG. 6 in the semiconductor device manufacturing method according to the third embodiment of the present invention;

FIG. 8 is a cross-sectional view of the device structure in a manufacturing step subsequent to the manufacturing step of FIG. 7 in the semiconductor device manufacturing method according to the third embodiment of the present invention;

FIG. 9 is a cross-sectional view of the device structure in a manufacturing step subsequent to the manufacturing step of FIG. 8 in the semiconductor device manufacturing method according to the third embodiment of the present invention;

FIG. 10 is a cross-sectional view of the device structure in a manufacturing step subsequent to the manufacturing step of FIG. 9 in the semiconductor device manufacturing method according to the third embodiment of the present invention;

FIG. 11 is a cross-sectional view of the device structure in a manufacturing step subsequent to the manufacturing step of FIG. 10 in the semiconductor device manufacturing method according to the third embodiment of the present invention;

FIG. 12 is a cross-sectional view of the device structure in a manufacturing step subsequent to the manufacturing step of FIG. 11 in the semiconductor device manufacturing method according to the third embodiment of the present invention;

FIG. 13 is a cross-sectional view of the device structure in a manufacturing step subsequent to the manufacturing step of FIG. 12 in the semiconductor device manufacturing method according to the third embodiment of the present invention; and

FIG. 14 is a cross-sectional view of the device structure in a manufacturing step subsequent to the manufacturing step of FIG. 13 in the semiconductor device manufacturing method according to the third embodiment of the present invention.

### DETAILED DESCRIPTION OF THE INVENTION

Embodiments of the present invention will be described below with reference to the drawings.

### First Embodiment

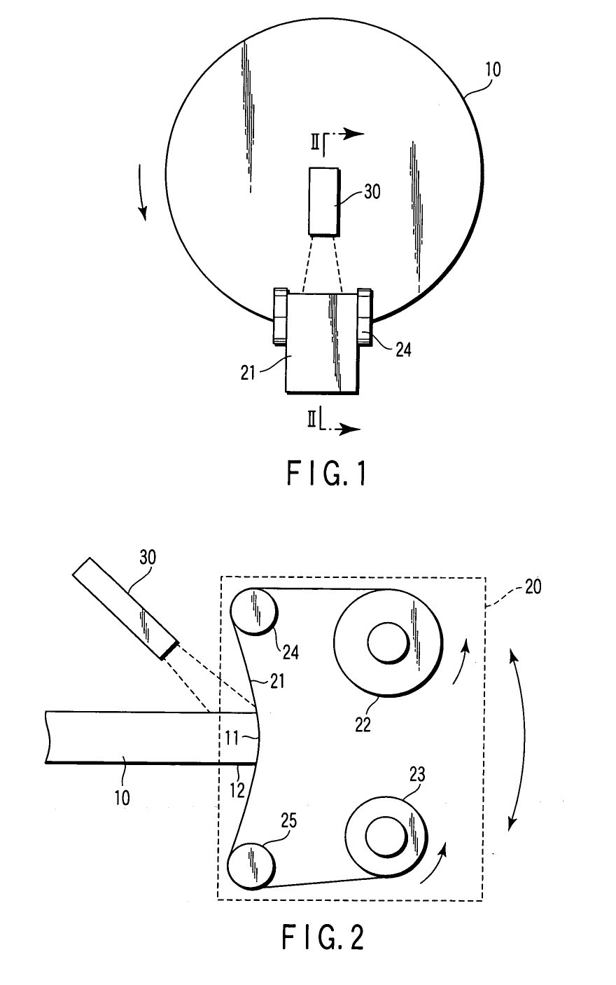

FIG. 1 and FIG. 2 are views for explaining a schematic configuration of a substrate processing apparatus according to a first embodiment of the present invention. More specifically, FIG. 1 is a plan view thereof, and FIG. 2 is a cross-sectional view taken along the line II-II of FIG. 1.

A polishing mechanism 20 is set for a semiconductor wafer 10 placed in the horizontal direction on a stage, not shown, to polish a bevel portion 11 of the wafer 10. The stage is rotatable about the axis of the wafer 10. A SiN film is deposited on edge, bevel, and notch portions, which are included in a peripheral portion of the wafer 10.

The polishing mechanism 20 comprises a polishing tape (i.e., polishing member) 21 coated with abrasive, a feed roller 22 for feeding the polishing tape 21, a take-up roller 23 for taking up the polishing tape 21, a feed side guide roller 24, and a take-up side guide roller 25. The polishing tape 21 is fed from the feed roller 22, is guided by the guide rollers 24 and 25, and is taken up by the take-up roller 23.

The polishing tape 21 is imparted predetermined tensions between the guide rollers 24 and 25, and concurrently, is pressed against the bevel portion 11 of the wafer 10 between the guide rollers 24 and 25. During the process of polishing the bevel portion 11 by the rotation of the stage, the polishing tape 21 is continuously and slowly fed from the feed roller 22, is guided by the guide rollers 24 and 25, and is taken up by the take-up roller 23.

A nozzle 30 is provided above a surface of the wafer 10 toward a slide portion between the bevel portion 11 of the wafer 10 and the polishing tape 21. During the process of polishing, a polishing liquid is supplied from the nozzle 30 toward the slide portion between the bevel portion 11 of the wafer 10 and the polishing tape 21.

The polishing mechanism 20 can be tilted overall in the state where the polishing tape 21 is in contact with the bevel portion 11 of the semiconductor wafer 10, so that polishing can be done not only for an outermost edge, but also for the entirety of the bevel portion 11.

In an example of the present embodiment, in order to remove a SiN film of 220 nm thick deposited on the bevel portion 11 of the semiconductor wafer 10 made of a silicon wafer, a polishing tape 21 formed by adhering diamond abrasive having a particle size of #4000 (JIS) by a binder on a tape base (width: 80 mm; thickness: 50 μm; and length: 50 μm) of PET (polyethylene terephthalate) was used. The bevel portion 11 was polished by using the polishing tape 21 in a manner that the stage on which the wafer 10 was placed is rotated at 500 rpm about the axis of the wafer 10 and the wafer 10 was rotated at 500 rpm. Concurrently, the polishing tape 21 was pressed at a load of 6N against the bevel portion 11. During the process of polishing, the polishing tape 21 was fed from the feed roller 22 at a rate of 10 mm/min, and a corresponding length of the polishing tape 21 was taken up by the take-up roller 23.

Conventionally, pure water is supplied during polishing; however, in the example, an aqueous solution containing 3 wt % (“wt %” represents the weight percent, which hereinafter will be indicated simply as “%”) polyethyleneimine (PEI) as an auxiliary polishing agent was supplied from the nozzle 30. As a consequence, although 60 seconds was needed to remove 220 nm thick SiN film in the case where the pure water was supplied, the time was reduced to 30 seconds by supplying the PEI-containing solution.

In a similar manner, the SiN film on an edge portion 12 of the wafer 10 was removed by tilting the polishing mechanism 20 with respect to the radial direction of the wafer 10 so that the polishing tape 21 contacts the edge portion 12 of the wafer 10.

It is considered that the time used for SiN film removing with the use of the PEI-containing solution is reduced for the reason that debris resulting from the polishing is not easily deposited on the polishing tape 21 because of surfactant effects of the PEI to thereby reduce deterioration in the polishing capability due to deposition of the debris on the polishing tape 21. It is also considered that the time used for SiN film removing with the use of the PEI-containing solution is reduced for the reason that since the PEI-containing solution is alkaline, also the Si substrate under the SiN-film is etched to thereby increase the rate of removing of the SiN film. Actually, the polishing rate with the use of the PEI-containing solution for Si is 1.2 times as high as the polishing rate achieved with the use of the pure water. Even with the use of, for example, TMAH (tetramethylammonium hydroxide) or a mixture of PEI and TMAH, effects similar to those as described above can be obtained.

However, even in the case of alkaline solutions, when, for example, a KOH alkaline solution is used, although the polishing rate for Si increases, the deposition of the debris onto the polishing tape 21 does not change from the case where the pure water is used, and thus the SiN film removing rate is not enhanced. Alternatively, when a polycarboxylic acid type surfactant, which is an acid surfactant, is used, while contamination of the polishing tape 21 decreases, the polishing rate for the Si substrate under the SiN film is not enhanced, and thus the SiN-film removing rate is not enhanced.

The following table shows polishing characteristics of the solutions.

TABLE

| | | | | | Polycarboxylic- |
|---|---|---|---|---|---|
| | | | | | acid type |
| | Pure water | PEI | TMAH | KOH | surfactant |
| Si polishing | X | ◯ | ◯ | ◯ | X |
| rate | | | | | |
| Tape | X | ◯ | ◯ | X | ◯ |
| contamination | | | | | |
| suppression | | | | | |
| SiN polishing | X | ◯ | ◯ | X | X |
| rate | | | | | |

From the Table, it can be known that the PEI solution and the TMAH solution is appropriate for polishing of the substrate peripheral portion having the SiN deposition.

When the PEI is used as the auxiliary polishing agent, the content of the PEI is preferably in the range of 0.1% to 50%. Similarly, when the TMAH is used as the auxiliary polishing agent, the content of the TMAH is preferably in the range of 0.1% to 25%. These ranges are preferable for the reasons that when the content of the auxiliary polishing agent is excessively small, the time necessary for removing the SiN film cannot be reduced so much, on the other hand, when the content of the auxiliary polishing agent is excessively large, the viscosity of the solution increases to the extent of possibly making it difficult to supply the polishing liquid through the nozzle 30.

Thus, according to the present embodiment, the solution containing the PEI or TMAH as the auxiliary polishing agent is supplied when the bevel portion 11 and edge portion 12 of the semiconductor wafer 10 are polished, and thus the SiN film deposited on the bevel portion 11 and edge portion 12 of the wafer 10 can be removed in a short time. Consequently, defect occurrence is suppressed, throughput is enhanced, and processing cost is reduced.

### Second Embodiment

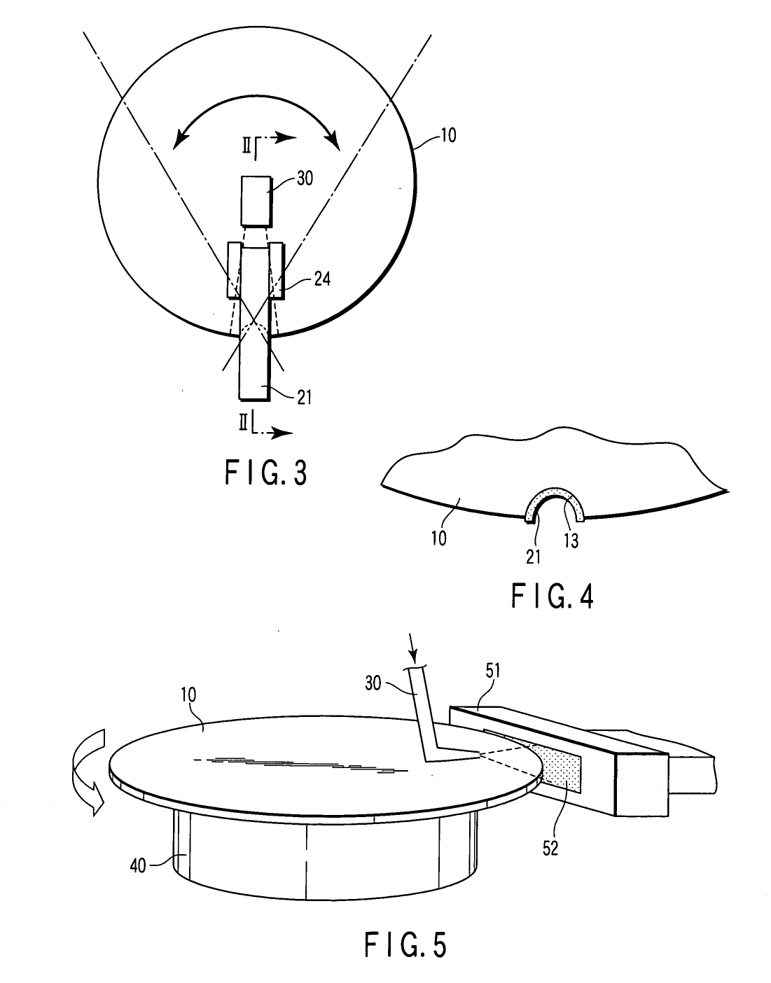

FIG. 3 is a plan view for explaining a schematic configuration of a substrate processing apparatus according to a second embodiment of the present invention. A cross-sectional view taken along the line II-II of FIG. 3 is substantially the same as that of FIG. 2, and is thus omitted. FIG. 4 is a view showing a contact state between a notch portion of a wafer and a polishing tape according to the second embodiment of the present invention. Like portions as those in FIG. 1 and FIG. 2 are designated with like numerals throughout the drawings, and detailed descriptions thereof will be omitted.

In the present embodiment, a notch portion 13 of the semiconductor wafer 10 is polished. Different from the case of the first embodiment, the stage is not rotated about the axis of the wafer 10, but is swung by a predetermined angle range, with the end of the notch portion 13 as being an axis, in the circumferential direction of the wafer 10. Alternatively, the configuration may be such that the entirety of the polishing mechanism 20 moves in a vertical direction (i.e., a direction extending from the front surface side to the reverse surface side of the wafer 10 or its opposite direction) in a predetermined distance range in the state where the polishing tape 21 is in contact with the notch portion 13.

As shown in FIG. 4, by being pressed against the wafer side, the polishing tape 21 is fed into the notch portion 13, so that the polishing tape 21 curved in the width direction of the polishing tape 21 (i.e., tape width direction) is uniformly contacted with the overall surface of the notch portion 13. In this state, the stage is swung, with the end of the notch portion 13 as the axis, in the circumferential direction of the wafer 10, or the polishing mechanism 20 is moved in the vertical direction, so that the notch portion 13 is polished by the polishing tape 21.

In an example of the present embodiment, a polishing tape 21 similar to that used in the first embodiment was used to remove a 220 nm thick SiN film deposited on the notch portion 13. However, the width of the polishing tape 21 used in the present case was 3 mm so as to be fed into the notch portion 13. The polishing tape 21 was pressed at a load of 100 gf against the notch portion 13, and concurrently, the stage was swung by an angle of ±30 degrees about the axis being the end of the notch portion 13 in the circumferential direction of the wafer 10, so that the notch portion 13 was polished by the polishing tape 21. Similarly as in the first embodiment, during the process of polishing, the polishing tape 21 was fed at the rate of 10 mm/min from the feed roller 22, and a corresponding length of the polishing tape 21 was taken up by the take-up roller 23.

Conventionally, pure water is supplied during polishing; however, in this example, a solution containing 4% TMAH as an auxiliary polishing agent was supplied from the nozzle 30. As a consequence, although 60 seconds was needed to remove 220 nm thick SiN film in the case where pure water was supplied, the time was reduced to 40 seconds by supplying the TMAH-containing solution.

With the second embodiment, by use of the TMAH-containing solution, a reduction effect of the SiN removing time similar to that in the first embodiment was obtained. Similarly as in the first embodiment, it is considered that the time can be reduced for the reasons that adhesion of the debris resulting from the polishing onto the polishing tape 21 can be suppressed, and etching of the Si substrate under the SiN film can be implemented.

In the embodiments described above, the PEI used as the auxiliary polishing agent may be of the type formed in the manner that hydrogen atoms in a polymer skeleton are substituted with a substituent, and the TMAH may be contained in the form of salts in the solution. Even with the use of these auxiliary polishing agents, similar effects as in the embodiments described above can be expected.

Further, in the first embodiment described above, a polishing member construction including a polishing member 52, such as a polishing tape, mounted to a polishing head 51 may be used, as shown in FIG. 5. According to this construction of the polishing member, bevel and edge portions of the wafer peripheral portions are polished by rotation of a stage 40. When the edge portion is polished, the polishing head 51 is tilted with respect to the radial direction of the wafer 10 so that the polishing head 51 becomes in contact with the edge portion. In this polishing member construction, different from the polishing tape in which the polishing portion moves, a portion of the polishing member 52 is continually used. Therefore, the effect of reducing the amount of debris adhered onto the polishing member is greatly advantageous in the construction such as described above.

### Third Embodiment

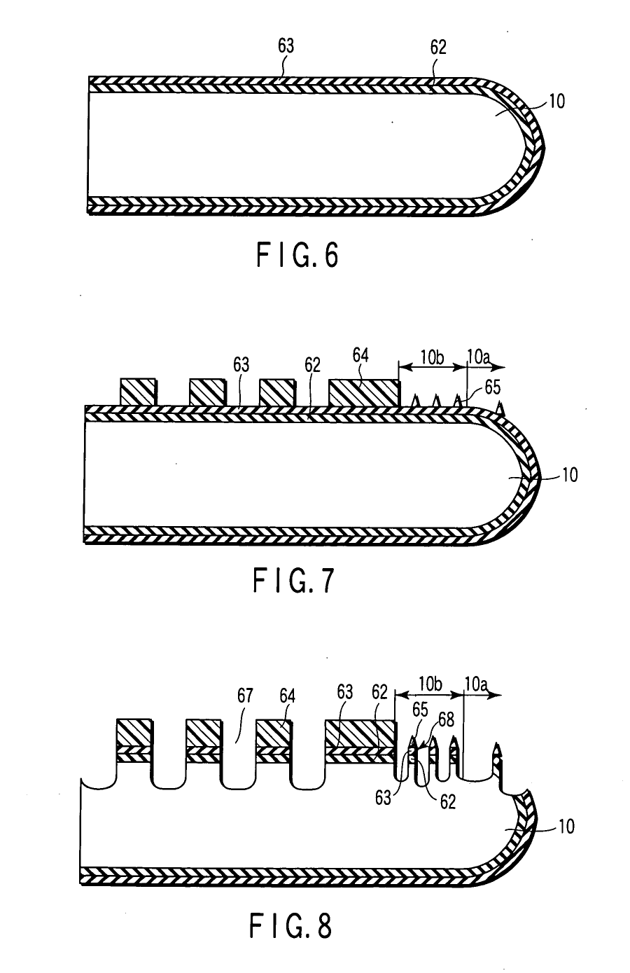

FIG. 6 to FIG. 14 are cross-sectional views in respective processing steps in a substrate processing method of a semiconductor device according to a third embodiment of the present invention.

In the present embodiment, a manufacturing method of a semiconductor device, more specifically, a DRAM (Dynamic Random Access Memory) cell, will be described below in relation to removal of an undesired SiN film formed on a peripheral portion of a semiconductor wafer during forming of a trench capacitor.

With reference to FIG. 6, a SiN (silicon nitride) film 62 and a SiO₂ film 63 (silicon oxide) are sequentially formed by a CVD (Chemical Vapor Deposition) process on the surface of a silicon wafer 10 as a semiconductor wafer to form a laminated insulation film on the wafer surface. Subsequently, as shown in FIG. 7, a resist pattern 64 is formed on the SiO₂ film 63 of the laminated insulation film. During the process of forming the resist pattern 64, there may be a case in which an undesired resist pattern 65 remains on a bevel portion 10a and an edge portion 10b of the peripheral portion of the wafer 10. Although not shown, an undesired resist pattern 65 may remain on a notch portion of the peripheral portion, as well.

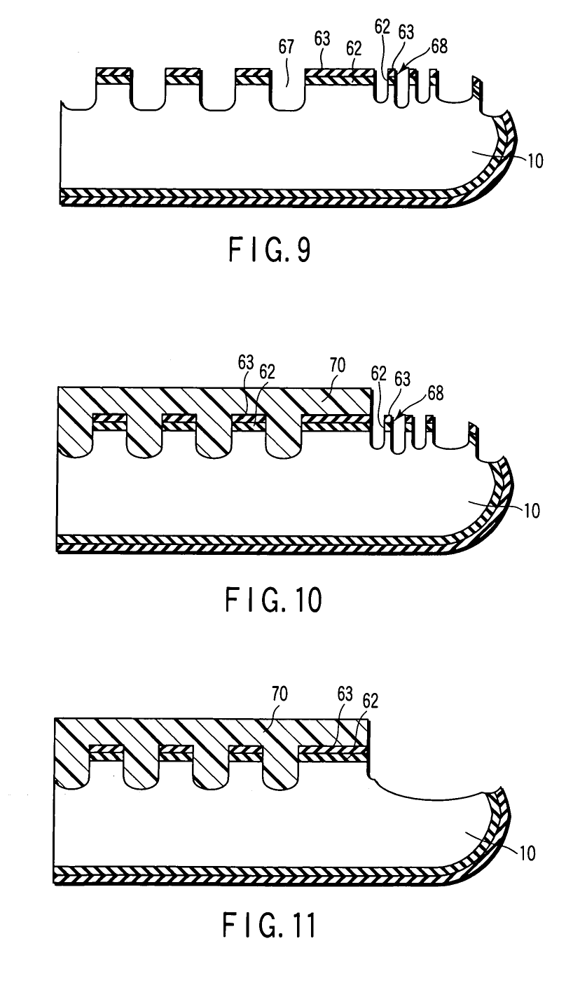

After forming the resist pattern 64 on the SiO₂ film 63 of the laminated insulation film, as described above, the SiO₂ film 63, the SiN film 62, and silicon wafer 10 are sequentially etched by RIE (Reactive Ion Etching), with the resist pattern 64 being used as a mask, to form trenches 67 for forming the capacitor of the DRAM cell, as shown in FIG. 8. In this etching process, the resist pattern 65 remaining on the bevel portion 10a and the edge portion 10b of the silicon wafer 10 functions as a mask to form thorn-like sharp protrusions on the bevel portion 10a and the edge portion 10b of the silicon wafer 10. In other words, thorn-like sharp protrusions including material film 68 formed of the SiN film 62 and the SiO₂ film 63 remain on the bevel portion 10a and the edge portion 10b of the wafer 10. In some cases, the thorn-like sharp protrusions are generated in such a manner that when the RIE is carried out to form the trenches 67, plasma does not well reach the peripheral portion of the semiconductor wafer 10 to cause an insufficient etching for the laminated insulation film formed of the SiN film 62 and the SiO₂ film 63, and this creates the SiN film 62 and the SiO₂ film 63 remaining on the peripheral portion of the semiconductor wafer 63, which function as a mask during the etching to thereby generate the thorn-like sharp protrusions. After forming the trenches 67, as described above, the resist pattern 64 is removed, as shown in FIG. 9.

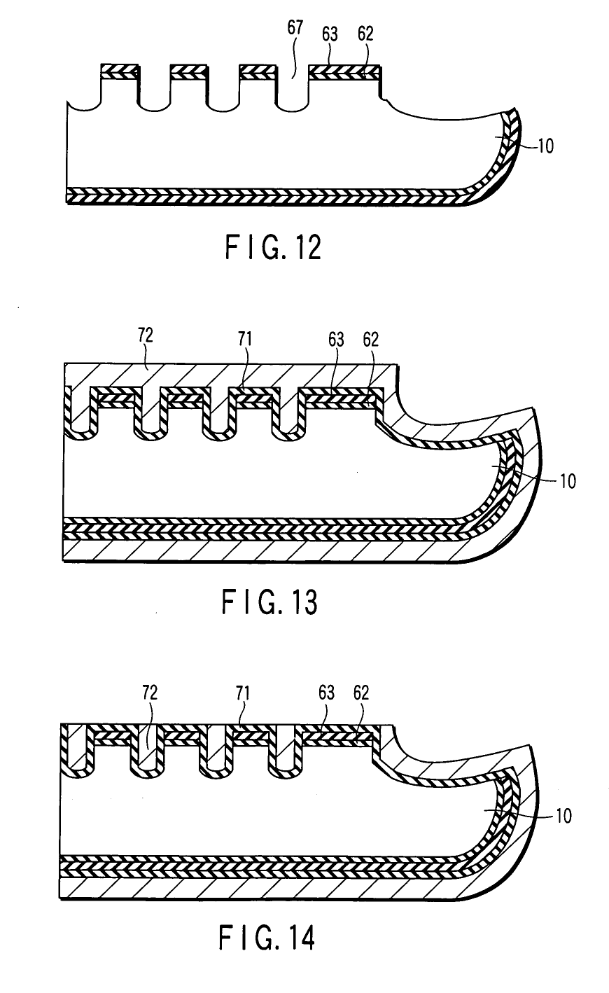

The protrusions including the material film 68 of the SiN film 62 and the SiO₂ film 63 remaining on the bevel portion 10a and the edge portion 10b of the wafer 10 become sources of contamination in subsequent processing steps. Thus, the protrusions generated on the bevel portion 10a and the edge portion 10b have to be removed. In order to remove the protrusions including the remaining material film 68, as shown in FIG. 10, first, a resist pattern 70 is formed in a device formation area of the wafer 10, i.e., in a area other than the bevel portion 10a and edge portion 10b, thereby to protect the device formation area. Then, the substrate processing method described in the first embodiment is carried out. That is, with reference to FIG. 2, the wafer 10 is placed on the stage, the wafer 10 is rotated by rotating the stage about the axis of the wafer 10, and concurrently, the polishing tape 21 is pressed against the bevel portion 10a, so that the bevel portion 10a is polished by the polishing tape 21. During the process of polishing, the polishing tape 21 is fed from the feed roller 22, and a corresponding length of the polishing tape 21 is taken up by the take-up roller 23. During the process of polishing, the solution containing 3% PEI (polyethyleneimine) as the auxiliary polishing agent is supplied from the nozzle 30. Further, the polishing mechanism 20 is tilted to contact the polishing tape 21 with the edge portion 10b of the wafer 10 to polish the edge portion 10b in a similar manner, so that the protrusions formed of the material film 68 and the Si material under the material film 68 are removed from the bevel portion 10a and the edge portion 10b, as shown in FIG. 11. Then, as shown in FIG. 12, the resist pattern 70 used as the protection film is removed.

Subsequently, as usual, an impurity is introduced in the inner wall of the trenches, and then, a SiON (silicon oxynitride) film 71 is formed on the inner wall of the trenches as a dielectric film of a capacitor. Thereafter, as shown in FIG. 13, a polysilicon film 72 is formed over the surface of the wafer 10. Subsequently, a CMP (Chemical Mechanical Polishing) process is performed for etch-back of the polysilicon film 72, so that electrodes formed of the polysilicon film 72 are formed in the trenches, as shown in FIG. 14. Through these steps, the capacitor of the DRAM cell is formed. Also in the present embodiment, the polishing time is reduced by use of the PEI-containing solution as the polishing liquid, consequently reducing the time necessary for the manufacture of the semiconductor device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A substrate processing method of polishing a peripheral portion of a substrate to-be-processed by sliding a polishing member and the peripheral portion of the substrate to each other to remove a SiN film deposited on the peripheral portion of the substrate, the method comprising:
supplying a solution containing at least one of polyethyleneimine and tetramethylammonium hydroxide to a slide portion between the peripheral portion of the substrate and the polishing member.

2. A substrate processing method according to claim 1, wherein the substrate is a semiconductor wafer, and the peripheral portion of the substrate is a bevel portion, an edge portion, or a notch portion of the semiconductor wafer.

3. A substrate processing method according to claim 2, wherein the semiconductor wafer is a silicon wafer.

4. A substrate processing method according to claim 1, wherein a content of the polyethyleneimine contained in the solution is in a range of 0.1 to 50 wt %.

5. A substrate processing method according to claim 1, wherein a content of the tetramethylammonium hydroxide contained in the solution is in a range of 0.1 to 25 wt %.

6. A substrate processing method according to claim 1, wherein a polishing tape comprising a resin base on a surface of which abrasive is adhered is used as the polishing member, and the polishing tape is brought into contact with and pressed against the peripheral portion of the substrate, while rotating a substrate holding mechanism holding the substrate.

7. A substrate processing method according to claim 6, wherein the substrate is a semiconductor wafer, and the peripheral portion of the substrate is a bevel portion or an edge portion of the semiconductor wafer.

8. A substrate processing method according to claim 1, wherein a polishing tape comprising a resin base on a surface of which abrasive is adhered is used as the polishing member, and the polishing tape is brought into contact with and pressed against the peripheral portion of the substrate, while swinging a substrate holding mechanism holding the substrate or moving a polishing mechanism including the polishing tape in a vertical direction.

9. A substrate processing method according to claim 8, wherein the substrate is a semiconductor wafer, and the peripheral portion of the substrate is a notch portion of the semiconductor wafer.

10. A substrate processing method according to claim 1, wherein a polishing tape mounted on a polishing head, comprising a resin base on a surface of which abrasive is adhered, is used as the polishing member, and the polishing tape is brought into contact with and pressed against the peripheral portion of the substrate, while rotating a substrate holding mechanism holding the substrate.

11. A substrate processing method according to claim 10, wherein the substrate is a semiconductor wafer, and the peripheral portion of the substrate is a bevel portion or an edge portion of the semiconductor wafer.

12. A semiconductor device manufacturing method comprising:
forming an insulation film containing SiN above a semiconductor wafer;
forming a resist pattern on the insulation film;
forming a trench passing through the insulation film and extending in a surface region of the semiconductor wafer by etching the insulation film and the semiconductor wafer, using the resist pattern as a mask;
removing the resist pattern; and
removing an undesired portion of the insulation film deposited on a peripheral portion of the semiconductor wafer by sliding the peripheral portion of the semiconductor wafer and a polishing member to each other while supplying a solution containing at least one selected from polyethyleneimine and tetramethylammonium hydroxide to a slide portion between the peripheral portion of the semiconductor wafer and the polishing member.

13. A semiconductor device manufacturing method according to claim 12, wherein the peripheral portion of the semiconductor wafer is a bevel portion, an edge portion, or a notch portion of the semiconductor wafer.

14. A semiconductor device manufacturing method according to claim 12, wherein the semiconductor wafer is a silicon wafer.

15. A semiconductor device manufacturing method according to claim 14, wherein a protrusion including the undesired portion of the insulation film and a portion of the silicon wafer under the undesired portion is removed by sliding the peripheral portion of the semiconductor wafer and the polishing member to each other.

16. A semiconductor device manufacturing method according to claim 12, wherein a content of the polyethyleneimine in the solution is in a range of 0.1 to 50 wt %.

17. A semiconductor device manufacturing method according to claim 12, wherein a content of the tetramethylammonium hydroxide in the solution is in a range of 0.1 to 25 wt %.

18. A substrate processing method according to 12, further comprising
forming a dielectric film on an inner wall of the trench after removing the undesired portion of the insulation film; and
filling an inside of the trench in which the dielectric film has been formed, with a conductive material.

19. A semiconductor device manufacturing method according to claim 18, wherein the dielectric film is a dielectric film of a trench capacitor structured in the trench.

20. A semiconductor device manufacturing method according to claim 19, wherein the conductive material forms an electrode of one side of the trench capacitor.
